(19) United States
(12) Patent Application Publication
(10) Pub. No.: US 2024/0128247 A1
(43) Pub. Date: Apr. 18, 2024

(54) PACKAGE ARCHITECTURE WITH GLASS CORE SUBSTRATE HAVING INTEGRATED INDUCTORS

(71) Applicant: Intel Corporation, Santa Clara, CA (US)

(72) Inventors: Brandon C. Marin, Gilbert, AZ (US); Kristof Kuwawi Darmawikarta, Chandler, AZ (US); Srinivas V. Pietambaram, Chandler, AZ (US); Gang Duan, Chandler, AZ (US); Jeremy Ecton, Gilbert, AZ (US); Suddhasattwa Nad, Chandler, AZ (US); Hiroki Tanaka, Gilbert, AZ (US)

(73) Assignee: Intel Corporation, Santa Clara, CA (US)

(21) Appl. No.: 18/046,635

(22) Filed: Oct. 14, 2022

(51) Int. Cl. H01L 25/16; H01F 27/02; H01F 27/28; H01F 27/29; H01F 41/00; H01F 41/04; H01L 21/48; H01L 23/00; H01L 23/538

(52) U.S. Cl. CPC H01L 25/16; H01F 27/022; H01F 27/2804; H01F 27/292; H01F 41/005; H01F 41/041; H01L 21/486; H01L 23/5384; H01L 23/5386; H01L 24/16; H01L 21/4853; H01L 2224/16235; H01L 2224/16267; H01L 2924/19042; H01L 2924/19103

(57) ABSTRACT

Embodiments described herein enable a microelectronic assembly that includes: a first substrate comprising glass and at least one inductor, the first substrate having a first side and an opposing second side; a second substrate coupled to the first side of the first substrate; and a plurality of integrated circuit (IC) dies. A first subset of the plurality of IC dies is directly coupled to the second side of the first substrate, a second subset of the plurality of IC dies is directly coupled to the second substrate adjacent to the first substrate, and a third subset of the plurality of IC dies is embedded in the second substrate between the first substrate and the second subset of the plurality of IC dies.

### TECHNICAL FIELD

The present disclosure relates to techniques, methods, and apparatus directed to a package architecture with glass core substrate having integrated inductors.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional views of an example microelectronic assembly according to some embodiments of the present disclosure.

FIG. 2A is a schematic cross-sectional view of a portion of an example microelectronic assembly according to some embodiments of the present disclosure.

FIG. 2B is a schematic top view of an inductor in the microelectronic assembly of FIG. 2A.

FIG. 3A is a schematic cross-sectional view of a portion of another example microelectronic assembly according to some other embodiments of the present disclosure.

FIG. 3B is a schematic perspective view of an inductor in the portion of microelectronic assembly of FIG. 3A.

FIG. 4A is a schematic cross-sectional view of a portion of another example microelectronic assembly according to some other embodiments of the present disclosure.

FIG. 4B is a schematic perspective view of a portion of an inductor in the microelectronic assembly of FIG. 4A.

FIGS. 5A-5H are schematic cross-sectional views of various stages of manufacture of an example microelectronic assembly according to some other embodiments of the present disclosure.

FIGS. 6A-6H are schematic cross-sectional views of various stages of manufacture of another example microelectronic assembly according to some other embodiments of the present disclosure.

FIGS. 7A-7H are schematic cross-sectional views of various stages of manufacture of yet another example microelectronic assembly according to some other embodiments of the present disclosure.

FIG. 8 is a cross-sectional view of a device package that includes one or more microelectronic assemblies in accordance with any of the embodiments disclosed herein.

FIG. 9 is a cross-sectional side view of a device assembly that includes one or more microelectronic assemblies in accordance with any of the embodiments disclosed herein.

FIG. 10 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

The trend in the processor industry is to move toward disaggregation, using multiple known good chiplets (smaller sized IC dies) made using different manufacturing technologies and assembling them together into one microprocessor using novel bonding techniques. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain universal serial bus (USB) standards, rather than for processing speed. Thus, by having different parts of the overall design separated into different dies, each one optimized in terms of design and manufacturing, the overall yield and cost of the combined die solution may be improved.

However, when IC dies are disaggregated thus, complexities arise with appropriate power distribution to these different IC dies. According to current market trend of servers, cloud computing, artificial intelligence (AI) and graphics, there is increasing demand for processors such as central processing units (CPUs) requiring high power and power density to fuel ever-increasing computing demands. To support such power consuming devices (e.g., consuming greater than 1000 W), a high input voltage (e.g., input voltage greater than 2.0V) integrated voltage regulator (IVR) packaged together with a CPU die may be used, for example, in a last power delivery stage. Such IVRs may be implemented in fully integrated form (Fully Integrated Voltage Regulator or FIVR), which is a buck convertor VR integrated on the CPU die itself. However, the FIVR strategy inherently suffers from specific technical limitations that prevent scaling up CPU computing and power capabilities to the level demanded by market trends.

Latest and future silicon process (e.g., manufacturing) technologies are increasingly tuned for improving and accelerating digital performance, for example, with shrinking device sizes, decreasing transistor voltages devices and added metal layers. However, this trend is inherently opposed to desired optimal process properties, such as high voltage, low resistance, and low cost, for an efficient power delivery circuit including IVRs. Because FIVRs are located on the CPU die, they necessarily use the same technology process node as the CPU die, which is typically an advanced process node that does not support efficient power delivery circuits. This creates several fundamental obstacles for keeping up with the rapid power scaling up demands of current and future CPUs.

On-package high-voltage discrete VRs provide many of the benefits of high-voltage FIVR. For example, they allow for reduction of overall through-platform resistive losses and reduce socket pin count. However, they have several disadvantages, such as: increased resistive loss and load-line related losses from lateral power distribution on the package; reduced area available for compute blocks on the package due to the area occupied by the VR dies and their supporting passives; and inability to perform fine-grained power management (PM) without addition of a low drop-out regulator (LDO) stage (thus not totally eliminating the area required for integrated regulation).

Some solutions to overcome many of the disadvantages described above include provisioning portions of the VR in the package and other portions in the IC dies. For example, inductors may be provisioned as coaxial metal inductor loop (MIL) in the core of the package substrate, whereas other elements of the VR and power management circuit may be provisioned in the IC dies. However, the presence of inductors in the package substrate causes warpage issues in regions where they are provisioned, which can affect the interconnect yield of IC dies attached to the package substrate in these regions. A potential solution is to move the coaxial MIL inductors to the periphery of the package substrate, minimizing warpage problems in the center where compute dies are typically provisioned. Even so, the warpage is not eliminated entirely.

Accordingly, embodiments described herein enable a microelectronic assembly that includes: a first substrate comprising glass and at least one inductor, the first substrate having a first side and an opposing second side; a second substrate coupled to the first side of the first substrate; and a plurality of IC dies. A first subset of the plurality of IC dies is directly coupled to the second side of the first substrate, a second subset of the plurality of IC dies is directly coupled to the second substrate adjacent to the first substrate, and a third subset of the plurality of IC dies is embedded in the second substrate between the first substrate and the second subset of the plurality of IC dies.

In another embodiment is disclosed herein a substrate, comprising: a core of a glass material; buildup layers on a first side and an opposing second side of the core; outer layers on the first side and the opposing second side of the core; and an inductor in the core. The buildup layers comprise an organic dielectric material and conductive vias in the organic dielectric material, the outer layers comprise solder resist material and conductive bond-pads in the solder resist material, the buildup layers are between the core and the outer layers, and a subset of the conductive vias in the buildup layer on the first side of the core conductively couple the inductor to the conductive bond-pads in the solder resist material on the first side of the core.

Other embodiments of the microelectronic assembly comprise: a package substrate having a medial region and a peripheral region around the medial region; an interposer coupled to the medial region of the package substrate, a first plurality of IC dies being coupled to a side of the interposer opposite the package substrate; a second plurality of IC dies in the peripheral region of the package substrate; and a plurality of other substrates coupled to the package substrate and the second plurality of IC dies such that each of the other substrate is between the package substrate and a corresponding IC die in the second plurality of IC dies. Each of the other substrate comprises a core of glass and at least one inductor embedded in the core, and the inductor is part of a power management circuit in the microelectronic assembly.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

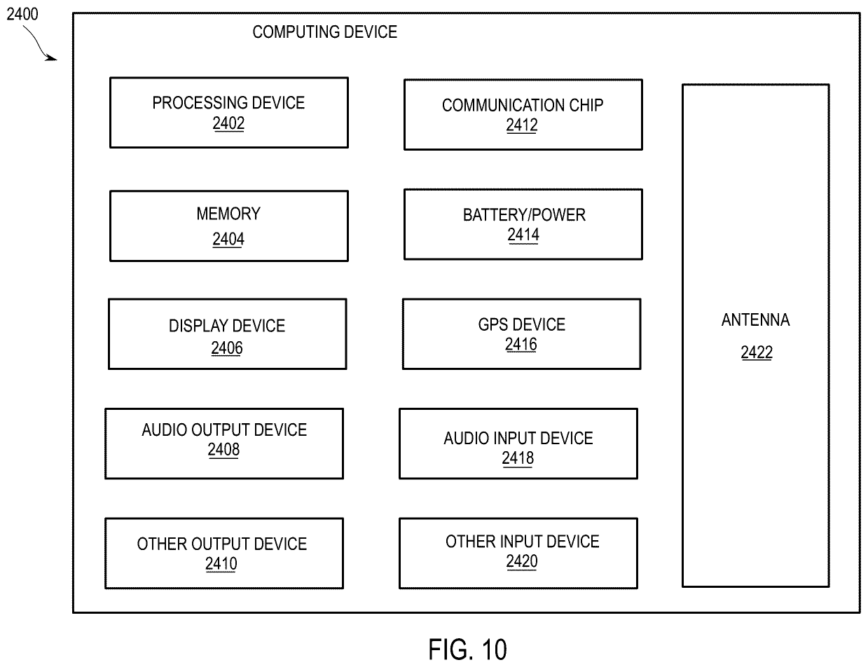

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

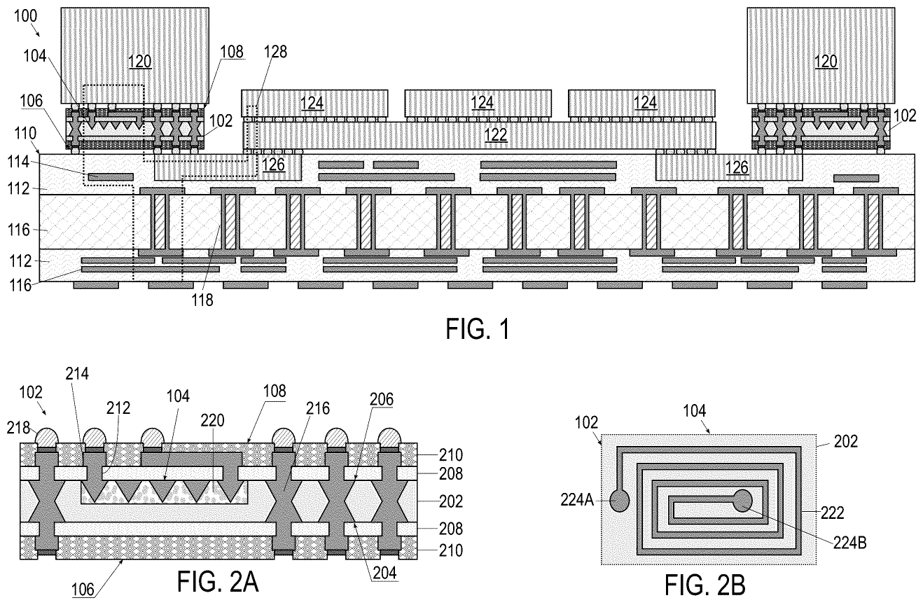

FIG. 1 is a schematic cross-sectional view of an example microelectronic assembly 100 according to some embodiments of the present disclosure. Microelectronic assembly 100 comprises a glass core substrate 102 (also termed a “patch substrate,” or “glass substrate” herein) and at least one inductor 104. Glass core substrate 102 has a first side 106 and an opposing second side 108. In various embodiments inductor 104 is conductively coupled to bond-pads on second side 108 of glass core substrate 102. A package substrate 110 is coupled to first side 106 of glass core substrate 102. Package substrate 110 has a medial region (i.e., proximate to the center) and a peripheral region (i.e., proximate to the periphery) around the medial region.

Package substrate 110 comprises buildup layers having an organic dielectric material 112 with conductive structures 114 therein. In some embodiments, conductive structures 114 comprise bond-pads, conductive traces and conductive vias. In some embodiments, a plurality of layers of conductive traces may be present, each layer separated by organic dielectric material 112 and conductively coupled to each other by conductive vias. Only some such structures are shown in the figure for ease of illustration and so as not to clutter the drawing. Any suitable configuration of conductive structures 114 may be disposed in package substrate 110 within the broad scope of the embodiments. In some embodiments, package substrate 110 may comprise a core 116 having a different composition than organic dielectric material 112; for example, organic dielectric material 112 may comprise polyimide or buildup film and core 116 may comprise fiber reinforced epoxy. In some other embodiments, organic dielectric material 112 may comprise one type of epoxy and core 116 may comprise a different type of epoxy. In some embodiments, core 116 may comprise an inorganic material, such as glass or ceramic. In some embodiments, package substrate 110 may comprise buildup layers having organic dielectric material 112 with conductive structures 114 therein on either side of core 116. In some such embodiments, through-hole vias (THVs) 118 through core 116 provide conductive coupling of conductive structures 114 on either side of core 116. The side of package substrate 110 opposite IC dies 120-126 may comprise bond-pads configured for coupling to a motherboard or socket of a motherboard (not shown).

Microelectronic assembly 100 further comprises a plurality of IC dies 120, 122, 124 and 126. IC dies 120 are in the peripheral region of package substrate 110, coupled to respective ones of glass core substrate 102. In other words, each glass core substrate 102 is coupled to package substrate 110 on first side 106 and to one of IC dies 120 on second side 108. Thus, glass core substrates 102 in microelectronic assembly 100 are in the peripheral region of package substrate 110. In many embodiments, IC dies 120 may comprise memory circuits. In some embodiments, IC dies 120 may comprise stacks of separate but similar IC dies, for example, a bank of memory arrays stacked one on top of another. In some embodiments, IC dies 120 may comprise peripheral interface circuits (e.g., PHY circuits) or other suitable electrical circuit appropriate for the functionality desired of microelectronic assembly 100.

IC dies 122 may comprise interposers, for example, comprising silicon, glass, ceramic, or organic dielectric materials, configured to couple together IC dies 124 opposite package substrate 110. In many embodiments, IC dies 124 may comprise compute circuits and each of IC die 122 may comprise a network circuit configured to conductively couple the compute circuits in IC dies 124 and memory circuits in IC dies 120. In various embodiments, IC dies 122 may be coupled directly to package substrate 110 laterally adjacent to glass core substrate 102.

IC dies 126 may comprise bridge dies configured to conductively couple laterally adjacent components, for example, glass core substrate 102 and IC die 122. Although the figure shows only one IC die 124 between glass core substrate 102 and IC die 122, it may be noted that such is only because of the cross-sectional view shown; in various embodiments, a plurality of IC dies 124 may be provisioned between glass core substrate 102 and IC die 122 in a direction perpendicular to the plane of the drawing. In various embodiments, IC dies 126 may be embedded in package substrate 110 suitably. IC dies 126 may be conductively coupled to glass core substrate 102 and IC die 122 by suitable interconnects.

In various embodiments, inductor 104 in glass core substrate 102 is part of a FIVR of a power management circuit 128 (shown in dotted lines) in microelectronic assembly 100. Power management circuit 128 may include various other electronic components distributed across one or more IC dies, for example, IC dies 120, 122, 124 and 126 suitably, as also in package substrate 110. For example, a power source on a motherboard (not shown) may be coupled to package substrate 110; the power source may be conductively coupled to IC dies 120, 122, 124 and 126 by way of THVs 118 and conductive structures 114. Such conductive structures 114 and THVs 118 are included in power management circuit 128 within the broad scope of the embodiments described herein.

FIG. 2A is a simplified cross-sectional view of glass core substrate 102 in microelectronic assembly 100 according to some embodiments of the present disclosure. Glass core substrate 102 comprises a core 202, in which is embedded inductor 104. Core 202 comprises glass in various embodiments. Core 202 comprises a first side 204 and a second side 206. Buildup layers 208 comprising an organic dielectric material may be disposed on either side of core 202. In various embodiments, the organic dielectric material of buildup layers 208 may comprise buildup film (e.g., ABF); in some embodiments, the organic dielectric material of buildup layers 208 may comprise polyimide. In some embodiments, buildup layers 208 may comprise a single layer of organic dielectric material and conductive traces (or vias); in other embodiments, buildup layers 208 may comprise a plurality of layers of conductive traces (and/or vias) and organic dielectric material, for example, like package substrate 110. In some embodiments, an outer layer 210, for example, comprising another organic dielectric material, may be disposed on either side of core 202 with buildup layers 208 being sandwiched between core 202 and outer layer 210. In various embodiments, the organic dielectric material of outer layers 210 may comprise solder resist.

Glass core substrate 102 may further comprise conductive vias 212 through buildup layers 208. Conductive bond-pads 214 may be disposed in outer layers 210 and surrounded by the solder resist material of outer layers 210. In various embodiments, inductor 104 may be conductively coupled to conductive vias 212 and conductive bond-pads on side 108 of glass core substrate 102 (and/or side 206 of core 202). Conductive vias 212 coupled to inductor 104 may conductively couple inductor 104 with some of conductive bond-pads 214. In various embodiments, conductive vias and bond-pads on side 204 of core 202 may be coupled to conductive vias and bond-pads on side 206 of core 202 by conductive through-glass vias (TGVs) 216. Interconnects 218 may facilitate bonding to IC dies 120 on side 108 of glass core substrate 102. Note that in microelectronic assembly 100, side 106 will be provisioned with interconnects as well; such interconnects are not shown in the figure merely for ease of illustration and not as a limitation. Interconnects 218 may comprise DTD interconnects as described in the previous subsection. In some embodiments, inductor 104 may comprise a planar spiral inductor formed in the glass of core 202. In some embodiments (e.g., as shown), the spiral conductive traces of inductor 104 may formed around a magnetic material 220. In other embodiments (not shown), the spiral conductive traces of inductor 104 may formed in the glass of core 202, without any surrounding ferromagnetic or magnetic materials.

A top view of inductor 104 comprising a planar spiral inductor is shown in FIG. 2B. Inductor 104 may comprise conductive traces 222 formed in the shape of a spiral with pads 224A and 224B coupled to conductive vias 212 (not shown) appropriately. In the figure, a rectangular spiral is shown; other shapes such as polygonal spirals and circular spirals are also encompassed in the broad scope of the embodiments. In some embodiments (not shown), conductive traces 222 may be embedded in magnetic material 220. In a general sense, the spiral inductor consists of several series-connected metal segments that together form a spiral (e.g., rectangular, polygonal, circular, etc.). Each segment may be configured to permit flow of current according to a time-varying voltage impressed on the segment, causing a time-varying electromagnetic field (EMF) from self-inductive and mutual-inductive effects (i.e. magnetic flux linkage from segment to segment).

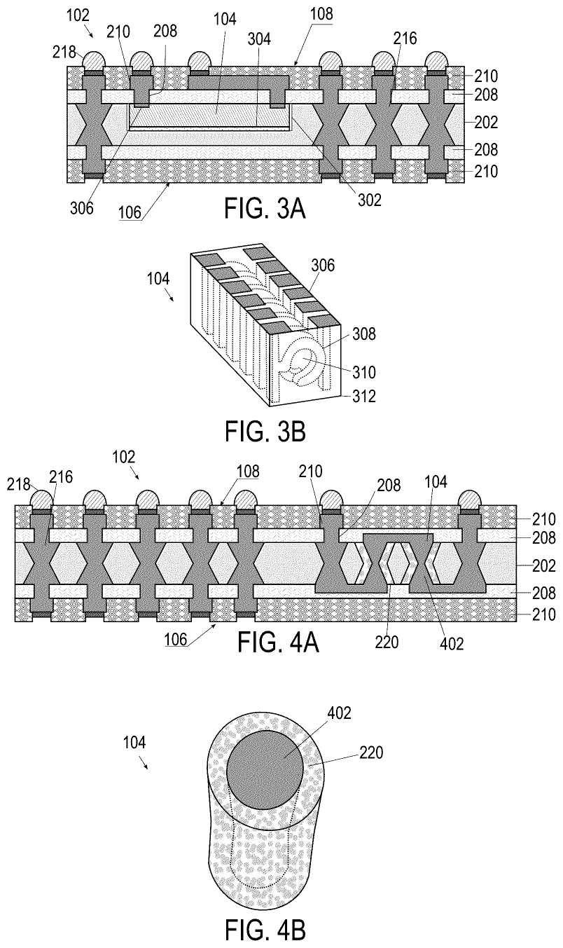

FIG. 3A is a simplified cross-sectional view of glass core substrate 102 in microelectronic assembly 100 according to some embodiments of the present disclosure. In the embodiment shown, inductor 104 in glass core substrate 102 may be a discrete component attached to a cavity 302 in core 202 by an adhesive 304. Inductor 104 may comprise bond-pads 306 that are conductively coupled to conductive vias 212 in buildup layers 208. A simplified perspective view of inductor 104 is shown in FIG. 3B, with certain internal structural components shown in dotted lines. Inductor 104 comprising a discrete component may have bond-pads 306 coupled to conductive traces 308 in the shape of a spiral around a magnetic core 310 and encased in a housing 312.

FIG. 4A is a simplified cross-sectional view of glass core substrate 102 in microelectronic assembly 100 according to some embodiments of the present disclosure. In the embodiment shown, inductor 104 may comprise a coaxial MIL inductor. In such embodiments, inductor 104 comprises a conductive core 402 surrounded coaxially by magnetic material 220, such that magnetic material 220 forms a coaxial magnetic sheath (e.g., shell, covering, etc.) around conductive core 402 as shown in FIG. 4B. Conductive core 402 may comprise a conductive TGV through core 202, similar to TGVs 216. The inductance of such coaxial MIL inductors may vary according to the height of magnetic material 220, from a minimum where no magnetic material 220 is used to a maximum where magnetic material 220 surrounds the entirety of conductive core 402.

In various embodiments, any of the features discussed with reference to any of FIGS. 1-4 herein may be combined with any other features to form a package with one or more IC dies as described herein. For example, in some microelectronic assemblies, some IC dies may be coupled by interconnects having solder and other IC dies may be coupled by non-solder bonds. Some such combinations are described above, but, in various embodiments, further combinations and modifications are possible. Various different embodiments described in different figures may be combined suitably based on particular needs within the broad scope of the embodiments.

Example Methods

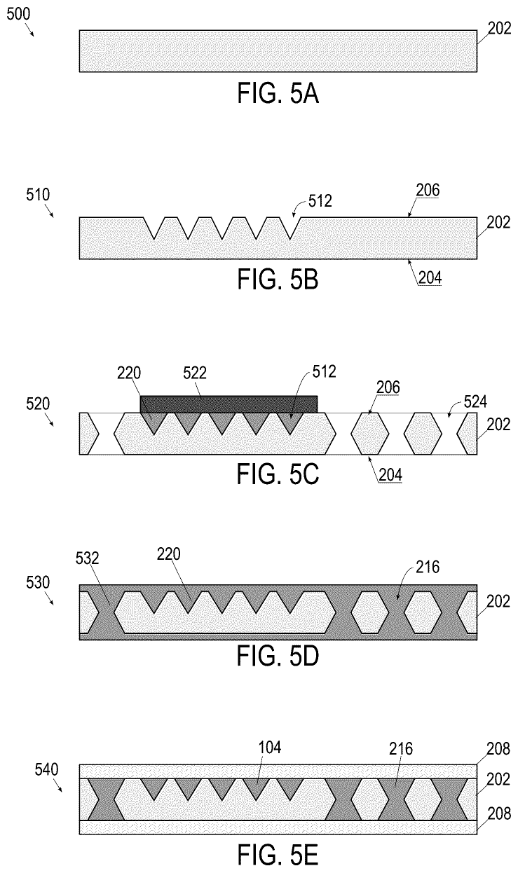

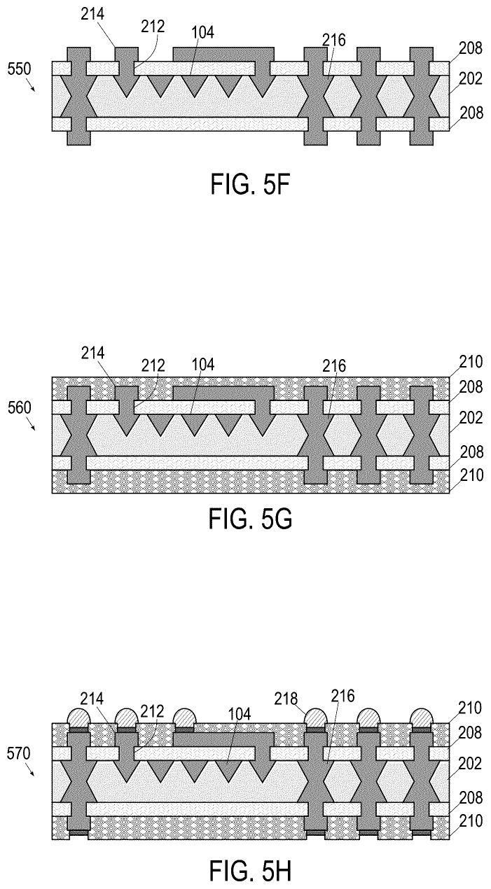

FIGS. 5A-5H are schematic cross-sectional views of various stages of manufacture of example microelectronic assembly 100 according to some other embodiments of the present disclosure. FIG. 5A shows a structure 500 comprising a panel of glass, corresponding to core 202 of glass core substrate 102. In various embodiments, the panel may be approximately 500 millimeters by 500 millimeters in area, or the size of a standard silicon wafer (e.g., 200 millimeters diameters) or other suitable size appropriate for large volume manufacturing in semiconductor processing facilities. Multiple ones of core 202 may be included in structure 500, and only one such core 202 is shown merely for ease of illustration, and not as a limitation.

FIG. 5B shows a structure 510 subsequent to forming spiral grooves 512 in the glass on side 206. Spiral grooves 512 correspond to the shape of a planar inductor such as inductor 104 of FIG. 2B. In various embodiments, spiral grooves 512 may be fabricated using any known method including photolithography, etching, laser direct writing (LDW), etc.

FIG. 5C shows a structure 520 subsequent to filling spiral grooves 512 with conductive material to form spiral conductive traces 222 of inductor 104. A photoresist material 522 may be deposited on spiral conductive traces 222, for example, to protect them, before forming through-holes 524 between sides 204 and 206. The shape of through-holes 524 may be according to the process used to fabricate them; for example, lithographic processes may result in tapers or hourglass profiles.

FIG. 5D shows a structure 530 subsequent to electroplating conductive material 532 to fill through-holes 5124 and form TGVs 216. At this stage of manufacture, a blanket layer of conductive material 532 may cover sides 204 and 206 of core 202.

FIG. 5E shows a structure 540 subsequent to lithographically patterning sides 204 and 206, removing excess conductive material 532, and depositing one or more layers of buildup layers 208 on either side of core 202.

FIG. 5F shows a structure 550 subsequent to forming conductive vias 212 through buildup layers 208 and bond-pads 214 on buildup layers 208.

FIG. 5G shows a structure 560 subsequent to depositing outer layers 210 comprising solder resist (or other organic dielectric material).

FIG. 5H shows a structure 570 subsequent to forming interconnects 218 through outer layers 210. In various embodiments, the panel may be divided into individual ones of glass core substrate 102 subsequently.

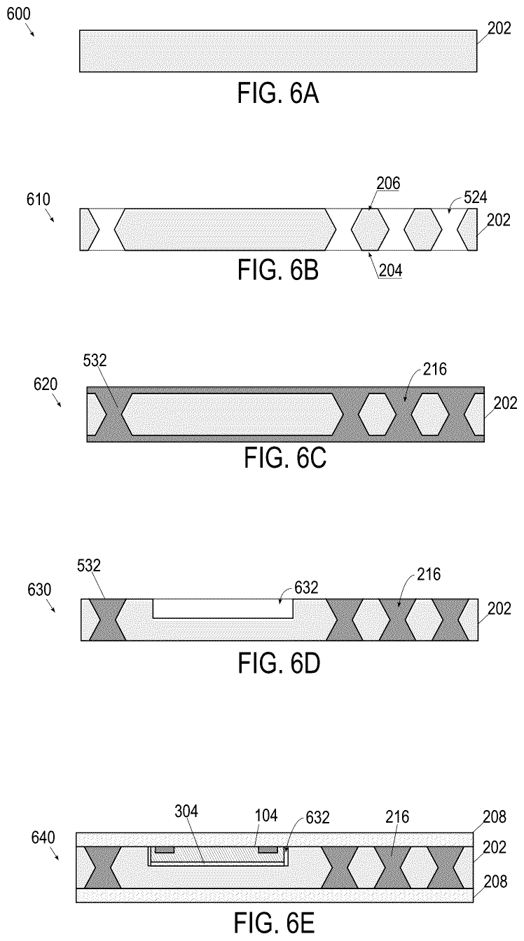

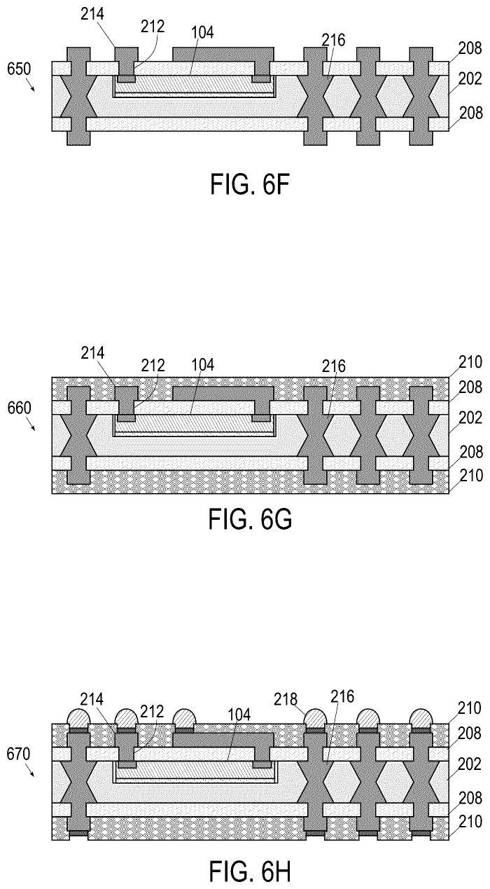

FIGS. 6A-6H are schematic cross-sectional views of various stages of manufacture of another example microelectronic assembly 100 according to some other embodiments of the present disclosure. FIG. 6A shows a structure 600 comprising a panel of glass, corresponding to core 202 of glass core substrate 102. In various embodiments, the panel may be approximately 500 millimeters by 500 millimeters in area, or the size of a standard silicon wafer (e.g., 200 millimeters diameters) or other suitable size appropriate for large volume manufacturing in semiconductor processing facilities. Multiple ones of core 202 may be included in structure 600, and only one such core 202 is shown merely for ease of illustration, and not as a limitation.

FIG. 6B shows a structure 610 subsequent to forming through-holes 524 between sides 204 and 206. The shape of through-holes 524 may be according to the process used to fabricate them; for example, lithographic processes may result in tapers or hourglass profiles.

FIG. 6C shows a structure 620 subsequent to electroplating conductive material 532 to fill through-holes 524 and form TGVs 216. At this stage of manufacture, a blanket layer of conductive material 532 may cover sides 204 and 206 of core 202.

FIG. 6D shows a structure 630 subsequent to forming a cavity 632 in core 202 and lithographically patterning sides 204 and 206, removing excess conductive material 532 to form TGVs 216. Cavity 632 may be formed by any suitable process, including photolithography, etching, LDW, etc.

FIG. 6E shows a structure 640 subsequent to attaching inductor 104 by adhesive 304 inside cavity 632 and depositing one or more layers of buildup layers 208 on either side of core 202.

FIG. 6F shows a structure 650 subsequent to forming conductive vias 212 through buildup layers 208 and bond-pads 214 on buildup layers 208.

FIG. 6G shows a structure 660 subsequent to depositing outer layers 210 comprising solder resist (or other organic dielectric material).

FIG. 6H shows a structure 670 subsequent to forming interconnects 218 through outer layers 210. In various embodiments, the panel may be divided into individual ones of glass core substrate 102 subsequently.

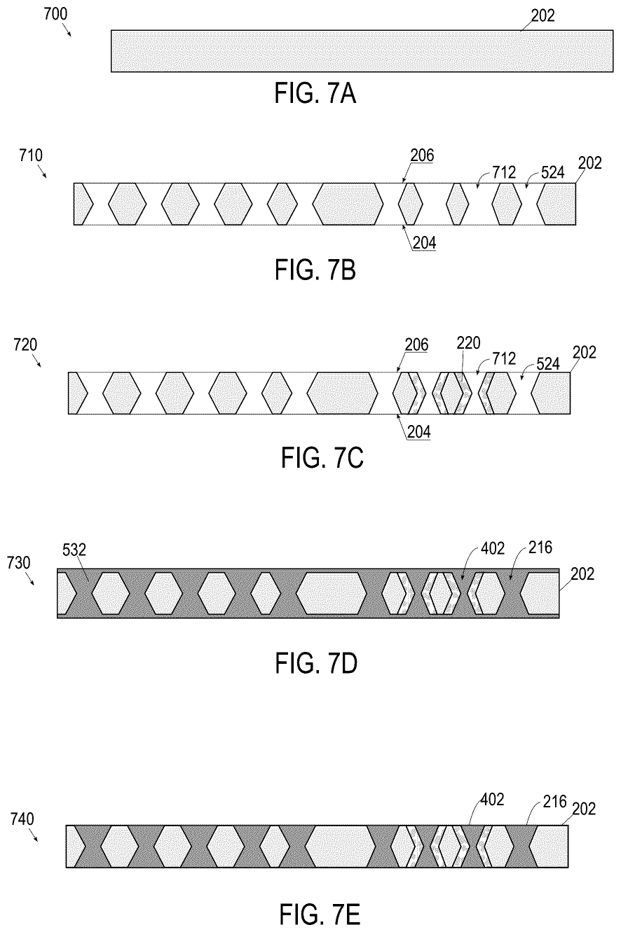

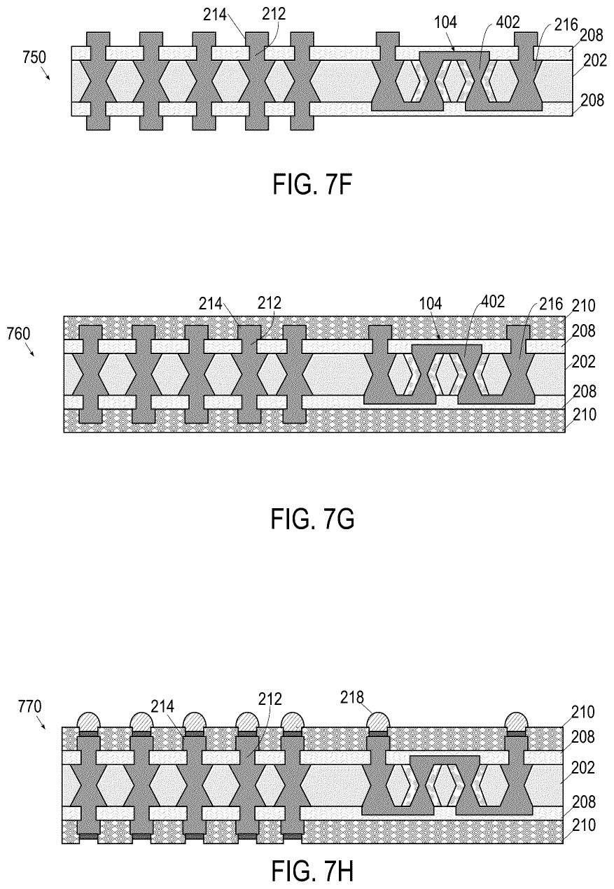

FIGS. 7A-7H are schematic cross-sectional views of various stages of manufacture of yet another example microelectronic assembly 100 according to some other embodiments of the present disclosure. FIG. 7A shows a structure 700 comprising a panel of glass, corresponding to core 202 of glass core substrate 102. In various embodiments, the panel may be approximately 500 millimeters by 500 millimeters in area, or the size of a standard silicon wafer (e.g., 200 millimeters diameters) or other suitable size appropriate for large volume manufacturing in semiconductor processing facilities. Multiple ones of core 202 may be included in structure 600, and only one such core 202 is shown merely for ease of illustration, and not as a limitation.

FIG. 7B shows a structure 710 subsequent to forming through-holes 524 and 712 between sides 204 and 206. The shape of through-holes 524 and 712 may be according to the process used to fabricate them; for example, lithographic processes may result in tapers or hourglass profiles. Through-hole 712, corresponding to structures of inductor 104 may have a larger diameter than through-hole 524 corresponding to TGVs 216.

FIG. 7C shows a structure 720 subsequent to depositing magnetic material 220 in through-holes 712.

FIG. 7D shows a structure 730 subsequent to electroplating conductive material 532 to fill through-holes 524 and 712 and form TGVs 216 and conductive 402 respectively. At this stage of manufacture, a blanket layer of conductive material 532 may cover sides 204 and 206 of core 202.

FIG. 7E shows a structure 740 subsequent to lithographically patterning sides 204 and 206, removing excess conductive material 532 to form TGVs 216 and conductive core 402.

FIG. 7F shows a structure 750 subsequent to depositing one or more layers of buildup layers 208 on either side of core 202, forming conductive vias 212 through buildup layers 208 and bond-pads 214 on buildup layers 208.

FIG. 7G shows a structure 860 subsequent to depositing outer layers 210 comprising solder resist (or other organic dielectric material).

FIG. 7H shows a structure 770 subsequent to forming interconnects 218 through outer layers 210. In various embodiments, the panel may be divided into individual ones of glass core substrate 102 subsequently.

Although FIGS. 5-7 illustrates various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 5-7 may be modified in accordance with the present disclosure to fabricate others of microelectronic assembly 100 disclosed herein. Although various operations are illustrated in FIGS. 5-7 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 5-7 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in FIGS. 5-7 may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

Example Devices and Components

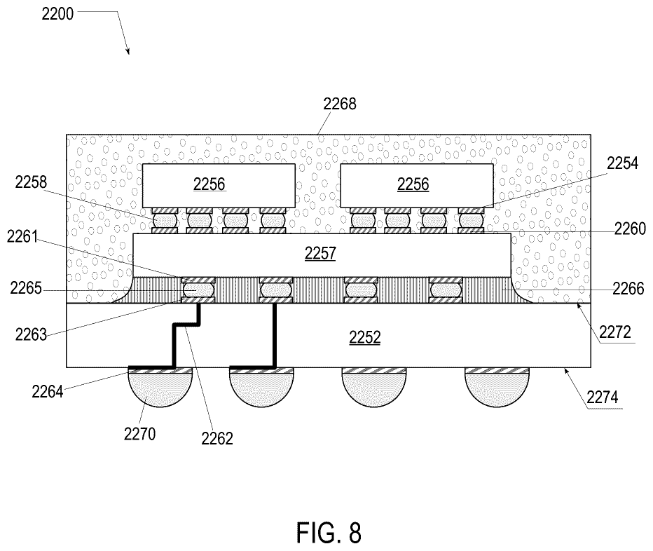

The packages disclosed herein, e.g., any of the embodiments shown in FIGS. 1-7 or any further embodiments described herein, may be included in any suitable electronic component. FIGS. 8-10 illustrate various examples of packages, assemblies, and devices that may be used with or include any of the IC packages as disclosed herein.

FIG. 8 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

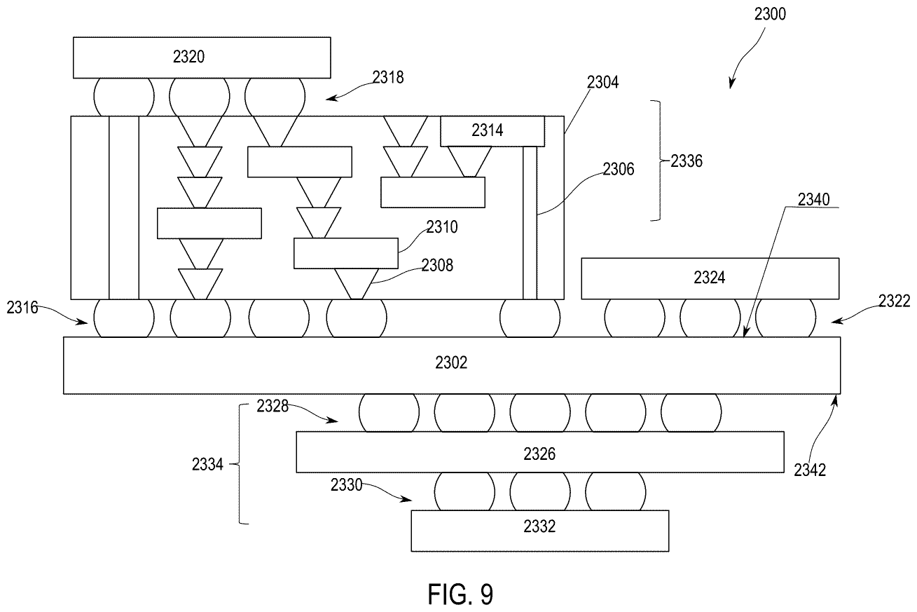

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 9.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 9 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 8. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 10 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 8). In yet another example, any one or more of the components of computing device 2400 may include an IC device assembly 2300 (e.g., as shown in FIG. 9).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIG. 1), comprising: a first substrate (e.g., 102) comprising glass and at least one inductor (e.g., 104), the first substrate having a first side (e.g., 106) and an opposing second side (e.g., 108); a second substrate (e.g., 110) coupled to the first side of the first substrate; and a plurality of IC dies (e.g., 120-126), in which: a first subset (e.g., 120) of the plurality of IC dies is directly coupled to the second side of the first substrate, a second subset (e.g., 122, 124) of the plurality of IC dies is directly coupled to the second substrate adjacent to the first substrate, and a third subset (e.g., 126) of the plurality of IC dies is embedded in the second substrate between the first substrate and the second subset of the plurality of IC dies.

Example 2 provides the microelectronic assembly of example 1, in which the at least one inductor in the first substrate is conductively coupled to the second side of the first substrate.

Example 3 provides the microelectronic assembly of any one of examples 1-2, in which the third subset of the plurality of IC dies is conductively coupled to the first substrate.

Example 4 provides the microelectronic assembly of any one of examples 1-3, in which (e.g., FIG. 2): the glass is a core (e.g., 202) of the first substrate, and the inductor is embedded in the core.

Example 5 provides the microelectronic assembly of example 4, in which the inductor is planar spiral inductor formed in the glass of the core.

Example 6 provides the microelectronic assembly of example 4, in which (e.g., FIG. 3) the inductor is a discrete component attached to a cavity (e.g., 302) in the core by an adhesive (e.g., 304).

Example 7 provides the microelectronic assembly of example 6, in which the inductor includes bond-pads (e.g., 306) conductively coupled to the second side of the core.

Example 8 provides the microelectronic assembly of example 6, in which the inductor includes conductive coils (e.g., 308) around a magnetic core (e.g., 310) and encased in a housing (e.g., 312)

Example 9 provides the microelectronic assembly of example 4, in which (e.g., FIG. 4) the inductor is a coaxial MIL in the glass of the core.

Example 10 provides the microelectronic assembly of example 9, in which: the coaxial MIL comprises a magnetic sheath (e.g., 220) around a conductive TGV (e.g., 402), and the conductive TGVs are conductively coupled to the second side of the core.

Example 11 provides the microelectronic assembly of any one of examples 4-10, in which (e.g., FIGS. 2-4) the first substrate further comprises: a first organic dielectric material (e.g., 208) on either side of the core, a second organic dielectric material (e.g., 210) on either side of the core, and the first organic dielectric material is between the second organic dielectric material and the core.

Example 12 provides the microelectronic assembly of example 11, in which: the first organic dielectric material is polyimide, and the second organic dielectric material is solder resist.

Example 13 provides the microelectronic assembly of any one of examples 11-12, in which: the first substrate further comprises: conductive vias (e.g., 212) through the first organic dielectric material; and conductive bond-pads (e.g., 214) in the second organic dielectric material on the second side of the first substrate, and the conductive vias conductively couple the at least one inductor to the conductive bond-pads.

Example 14 provides the microelectronic assembly of any one of examples 1-13, in which the first subset of the plurality of IC dies comprises a stack of IC dies.

Example 15 provides the microelectronic assembly of any one of examples 1-14, in which the first subset of the plurality of IC dies comprises memory circuits.

Example 16 provides the microelectronic assembly of any one of examples 1-15, in which the second subset of the plurality of IC dies comprises a stack of IC dies.

Example 17 provides the microelectronic assembly of any one of examples 1-16, in which: the second subset of the plurality of IC dies comprises an interposer and a fourth subset of the plurality of IC dies, the fourth subset of the plurality of IC dies is attached to the interposer, the interposer is attached to the second substrate, and the interposer is between the second substrate and the fourth subset of the plurality of IC dies.

Example 18 provides the microelectronic assembly of example 17, in which: the interposer comprises network circuits, and the fourth subset of the plurality of IC dies comprises compute circuits coupled by the network circuits of the interposer.

Example 19 provides the microelectronic assembly of any one of examples 1-18, in which the at least one inductor in the first substrate is part of a FIVR of a power management circuit (e.g., 128) in the microelectronic assembly.

Example 20 provides the microelectronic assembly of example 19, in which the FIVR circuit includes components in the first plurality of IC dies, the second substrate, the second plurality of IC dies and the third subset of the plurality of IC dies.

Example 21 provides a substrate, comprising: a core (e.g., 202) of a glass material; buildup layers (e.g., 204) on a first side (e.g., 204) and an opposing second side (e.g., 206) of the core; outer layers (e.g., 206) on the first side and the opposing second side of the core; and an inductor (e.g., 104) in the core, in which: the buildup layers comprise an organic dielectric material and conductive vias in the organic dielectric material, the outer layers comprise solder resist material and conductive bond-pads in the solder resist material, the buildup layers are between the core and the outer layers, and a subset of the conductive vias (e.g., 208) in the buildup layer on the first side of the core conductively couple the inductor to the conductive bond-pads in the solder resist material on the first side of the core.

Example 22 provides the substrate of example 21, in which: the inductor is fabricated as part of the core, and the inductor comprises a planar inductor having conductive spirals in a plane parallel to the first side of the core.

Example 23 provides the substrate of example 21, in which: the inductor is fabricated as part of the core, and the inductor comprises a coaxial MIL inductor.

Example 24 provides the substrate of example 21, in which: the inductor is a discrete component attached to a cavity in the core, and the inductor comprises conductive spirals in a plane orthogonal to the first side of the core.

Example 25 provides the substrate of any one of examples 21-24, in which the substrate is configured to be attached to an IC die on a first side of the substrate proximate to the first side of the core, and to a package substrate on a second side of the substrate proximate to the second side of the core.

Example 26 provides the substrate of example 25, in which: the IC die is a first IC die, a second IC die is embedded in the package substrate, and the substrate is configured to be conductively coupled to the second IC die.

Example 27 provides the substrate of example 26, in which the second IC die is configured to be conductively coupled to a third IC die attached to the package substrate laterally adjacent to the substrate.

Example 28 provides the substrate of example 27, in which: the first IC die comprises memory circuits, the second IC die comprises bridge circuits, the third IC die comprises compute circuits.

Example 29 provides the substrate of any one of examples 21-28, in which: the inductor in the substrate is part of a FIVR of a power management circuit in a microelectronic assembly.

Example 30 provides the substrate of any one of examples 27-29, in which the substrate is configured to be located proximate to a periphery of the package substrate and the third IC die is located proximate to a center of the package substrate.

Example 31 provides a microelectronic assembly (e.g., 100, FIG. 1), comprising: a first substrate having a medial region and a peripheral region around the medial region; an interposer coupled to the medial region of the first substrate, a first plurality of IC dies being coupled to a side of the interposer opposite to the first substrate; a second plurality of IC dies in the peripheral region of the first substrate; and a plurality of second substrates coupled to the first substrate and the second plurality of IC dies such that each second substrate is between the first substrate and a corresponding IC die in the second plurality of IC dies, in which: each second substrate comprises a core of glass and at least one inductor embedded in the core, and the inductor is part of a power management circuit in the microelectronic assembly.

Example 32 provides the microelectronic assembly of example 31, in which each second substrate comprises an organic dielectric material on either side of the core.

Example 33 provides the microelectronic assembly of example 32, in which the organic dielectric material comprises a polyimide or buildup film.

Example 34 provides the microelectronic assembly of any one of examples 31-33, in which the inductor in any second substrate is conductively coupled to the corresponding IC die of the second plurality of IC dies to which the respective second substrate is coupled.

Example 35 provides the microelectronic assembly of any one of examples 31-34, in which the second plurality of IC dies is conductively coupled to the interposer through one or more bridge dies in the first substrate.

Example 36 provides the microelectronic assembly of any one of examples 31-35, in which the inductor is one of: a planar inductor, a discrete inductor, or a coaxial MIL inductor.

Example 37 provides the microelectronic assembly of any one of examples 31-36, in which: the first plurality of IC dies comprises compute circuits, and at least a subset of the second plurality of IC dies comprises memory circuits.

Example 38 provides a method, comprising: providing a panel of glass; coupling an inductor in the panel; forming through-holes in the panel; plating the through-holes with conductive material; patterning the plated conductive material; depositing organic dielectric material on either side of the panel; forming conductive vias through the organic dielectric material; forming bond-pads on the organic dielectric material; depositing solder resist over the organic dielectric material; and forming interconnects through the solder resist such that the interconnects are conductively coupled to the bond-pads.

Example 39 provides the method of example 38, in which coupling the inductor comprises: forming planar spiral grooves on a surface of the panel by a laser direct write process; and filling the grooves with conductive material.

Example 40 provides the method of example 38, in which coupling the inductor comprises: forming a cavity in the panel; and attaching a discrete inductor inside the cavity with adhesive.

Example 41 provides the method of example 40, in which coupling the inductor is subsequent to plating the through-holes.

Example 42 provides the method of example 38, in which coupling the inductor comprises: forming a through-hole in the panel; depositing a coating of magnetic material in the through-hole, leaving a cavity; and filling the cavity with conductive material to form a conductive core within a magnetic sheath comprising the magnetic material.

Example 43 provides the method of any one of examples 38-42, in which forming through-holes in the panel comprises laser drilling through the panel.

Example 44 provides the method of any one of examples 38-43, in which the organic dielectric material comprises a polyimide or buildup film.

Example 45 provides the method of any one of examples 38-44, in which the interconnects comprise solder.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first substrate comprising glass and at least one inductor, the first substrate having a first side and an opposing second side;
a second substrate coupled to the first side of the first substrate; and
a plurality of integrated circuit (IC) dies,
wherein:
a first subset of the plurality of IC dies is directly coupled to the second side of the first substrate,
a second subset of the plurality of IC dies is directly coupled to the second substrate adjacent to the first substrate, and
a third subset of the plurality of IC dies is embedded in the second substrate between the first substrate and the second subset of the plurality of IC dies.

2. The microelectronic assembly of claim 1, wherein:
the glass is a core of the first substrate, and
the inductor is embedded in the core.

3. The microelectronic assembly of claim 2, wherein the inductor is planar spiral inductor formed in the glass of the core.

4. The microelectronic assembly of claim 2, wherein the inductor is a discrete component attached to a cavity in the core by an adhesive.

5. The microelectronic assembly of claim 2, wherein the inductor is a coaxial metal inductor loop (MIL) in the glass of the core.

6. The microelectronic assembly of claim 2, wherein the first substrate further comprises:
a first organic dielectric material on either side of the core,
a second organic dielectric material on either side of the core, and
the first organic dielectric material is between the second organic dielectric material and the core.

7. The microelectronic assembly of claim 1, wherein:
the second subset of the plurality of IC dies comprises an interposer and a fourth subset of the plurality of IC dies,
the fourth subset of the plurality of IC dies is attached to the interposer,
the interposer is attached to the second substrate, and
the interposer is between the second substrate and the fourth subset of the plurality of IC dies.

8. The microelectronic assembly of claim 1, wherein the at least one inductor in the first substrate is part of a fully integrated voltage regulator (FIVR) of a power management circuit in the microelectronic assembly.

9. A substrate, comprising:
a core of a glass material;
buildup layers on a first side and an opposing second side of the core;
outer layers on the first side and the opposing second side of the core; and
an inductor in the core,
wherein:
the buildup layers comprise an organic dielectric material and conductive vias in the organic dielectric material,
the outer layers comprise solder resist material and conductive bond-pads in the solder resist material,
the buildup layers are between the core and the outer layers, and
a subset of the conductive vias in the buildup layer on the first side of the core conductively couple the inductor to the conductive bond-pads in the solder resist material on the first side of the core.

10. The substrate of claim 9, wherein:
the inductor is fabricated as part of the core, and
the inductor comprises a planar inductor having conductive spirals in a plane parallel to the first side of the core.

11. The substrate of claim 9, wherein:
the inductor is fabricated as part of the core, and
the inductor comprises a coaxial MIL inductor.

12. The substrate of claim 9, wherein:
the inductor is a discrete component attached to a cavity in the core, and
the inductor comprises conductive spirals in a plane orthogonal to the first side of the core.

13. The substrate of claim 9, wherein the substrate is configured to be attached to an IC die on a first side of the substrate proximate to the first side of the core, and to a package substrate on a second side of the substrate proximate to the second side of the core.

14. The substrate of claim 13, wherein:
the IC die is a first IC die,
a second IC die is embedded in the package substrate, and
the substrate is configured to be conductively coupled to the second IC die.

15. The substrate of claim 13, wherein the substrate is configured to be located proximate to a periphery of the package substrate and a second IC die adjacent to the substrate is located proximate to a center of the package substrate.

16. A microelectronic assembly, comprising:
a first substrate having a medial region and a peripheral region around the medial region;
an interposer coupled to the medial region of the first substrate, a first plurality of IC dies being coupled to a side of the interposer opposite to the first substrate;
a second plurality of IC dies in the peripheral region of the first substrate; and
a plurality of second substrates coupled to the first substrate and the second plurality of IC dies such that each second substrate is between the first substrate and a corresponding IC die in the second plurality of IC dies,
wherein:
each second substrate comprises a core of glass and at least one inductor embedded in the core, and
the inductor is part of a power management circuit in the microelectronic assembly.

17. The microelectronic assembly of claim 16, wherein each second substrate comprises an organic dielectric material on either side of the core.

18. The microelectronic assembly of claim 17, wherein the organic dielectric material comprises a polyimide or buildup film.

19. The microelectronic assembly of claim 16, wherein the second plurality of IC dies is conductively coupled to the interposer through one or more bridge dies in the first substrate.

20. The microelectronic assembly of claim 16, wherein the inductor is one of:
a planar inductor,
a discrete inductor, or
a coaxial MIL inductor.
